(19) United States
(12) Patent Application Publication
(10) Pub. No.: US 2024/0148133 A1
(43) Pub. Date: May 9, 2024

(54) BRUSH FOR CLEANING A WAFER

(71) Applicant: Samsung Electronics Co., Ltd., Suwon-si (KR)

(72) Inventors: Jeongmin Na, Suwon-si (KR); Songyun Kang, Suwon-si (KR); Sungyong Park, Suwon-si (KR)

(73) Assignee: Samsung Electronics Co., Ltd., Suwon-si (KR)

(21) Appl. No.: 18/204,971

(22) Filed: Jun. 2, 2023

(30) Foreign Application Priority Data
Nov. 9, 2022 (KR) 10-2022-0148446

(51) Int. Cl. A46B 9/06; A46B 9/02; A46D 1/00

(52) U.S. Cl. CPC A46B 9/06; A46B 9/026; A46D 1/02; A46B 2200/3073

(57) ABSTRACT

A brush for cleaning a wafer includes a core extending lengthwise in a first direction, a brushing roller arranged on an outer circumferential surface of the core and having a first region and a second region defined at an outer circumferential surface of the brushing roller, a plurality of first brushing bristles extending from the first region in a radial direction of the brushing roller, wherein the radial direction of the brushing roller is perpendicular to the first direction, and a plurality of second brushing bristles extending from the second region in the radial direction of the brushing roller. Each of the plurality of first brushing bristles has a first shape, and each of the plurality of second brushing bristles has a second shape different from the first shape.

### CROSS-RELATED APPLICATION

This application claims priority under 35 USC § 119 to Korean Patent Application No. 10-2022-0148446, filed on Nov. 9, 2022, in the Korean Intellectual Property Office (KIPO), the contents of which are herein incorporated by reference in their entirety.

### BACKGROUND

### 1. Field

Example embodiments relate to a brush for cleaning a wafer. More particularly, example embodiments relate to a brush for removing particles from a wafer after a chemical mechanical polishing process is performed.

### 2. Description of the Related Art

Generally, after performing a chemical mechanical polishing (CMP) process on a wafer, a cleaning process may be performed to remove particles from the wafer. The cleaning process may be performed using a brush. The brush may include brushing bristles for contacting the rotated wafer to remove the particles from the wafer.

According to related arts, the brush may not have a function for controlling pressures applied to the wafer from the brushing bristles by regions of the wafer. Thus, a contact time of the brushing bristles with an edge region of the wafer may be relatively longer than a contact time of the brushing bristles with a central region of the wafer. When the brushing bristles may contact the central region of the wafer for a long time, a circuit structure in the central region of the wafer as well as the particles in the central region of the wafer may be partially removed.

### SUMMARY

Example embodiments provide a brush for cleaning a wafer that may be capable of controlling pressures to the wafer by regions of the wafer.

According to example embodiments, a brush for cleaning a wafer includes a core extending lengthwise in a first direction, a brushing roller arranged on an outer circumferential surface of the core and having a first region and a second region defined at an outer circumferential surface of the brushing roller, a plurality of first brushing bristles extending from the first region in a radial direction of the brushing roller, wherein the radial direction of the brushing roller is perpendicular to the first direction, and a plurality of second brushing bristles extending from the second region in the radial direction of the brushing roller. Each of the plurality of first brushing bristles has a first shape, and each of the plurality of second brushing bristles has a second shape different from the first shape.

According to example embodiments, a brush for cleaning a wafer includes a core extending lengthwise in a first direction, a brushing roller arranged on an outer circumferential surface of the core and having a central region and an edge region defined at an outer circumferential surface of the brushing roller, a plurality of first brushing bristles, wherein each of the plurality of first brushing bristles has a cylindrical shape that extends from the central region in a radial direction of the brushing roller, and wherein each of the plurality of first brushing bristles contacts a central region of the wafer at a first pressure, and a plurality of second brushing bristles, wherein each of the plurality of second brushing bristles has a truncated conical shape that extends from the edge region in the radial direction of the brushing roller, and wherein each of the plurality of second brushing bristles contacts an edge region of the wafer at a second pressure higher than the first pressure. The plurality of first and second brushing bristles have substantially the same height. Each of the plurality of second brushing bristles comprises a compression surface, a connection surface, and a side surface connecting the compression surface to the connection surface. The compression surface contacts the edge region of the wafer at the second pressure. The connection surface is connected to the brushing roller. The compression surface has a first radius, and the connection surface has a second radius longer than the first radius.

According to example embodiments, a brush for cleaning a wafer includes a core extending lengthwise in a first direction, a brushing roller arranged on an outer circumferential surface of the core and having a central region and an edge region defined at an outer circumferential surface of the brushing roller, a plurality of first brushing bristles, wherein each of the plurality of first brushing bristles has a cylindrical shape that extends from the central region in a radial direction of the brushing roller, and wherein each of the plurality of first brushing bristles contacts a central region of the wafer at a first pressure, and a plurality of second brushing bristles, wherein each of the plurality of second brushing bristles has a truncated conical shape that extends from the edge region in the radial direction of the brushing roller, and wherein each of the plurality of second brushing bristles contacts an edge region of the wafer at a second pressure higher than the first pressure. The plurality of first and second brushing bristles have substantially the same height. Each of the second brushing bristles comprises a compression surface, a connection surface, and a side surface connecting the compression surface to the connection surface. The compression surface contacts the edge region of the wafer at the second pressure. The connection surface is connected to the brushing roller. The compression surface has a first radius, and the connection surface has a second radius longer than the first radius. The plurality of second brushing bristles include a plurality of brushing bristles that are arranged along the first direction, and the plurality of second radii of the plurality of brushing bristles are gradually increased in a second direction from the central region to the edge region of the brushing roller. The second direction is parallel to the first direction.

According to example embodiments, the second pressure, which may be applied to the edge region of the wafer from the second brushing bristles having the truncated conical shape in the edge region of the brushing roller, may be higher than the first pressure, which may be applied to the central region of the wafer from the first brushing bristles having the cylindrical shape in the central region of the brushing roller. Thus, particle removal efficiency by the second brushing bristles may be higher than particle removal efficiency by the first brushing bristles. Therefore, a time for removing particles in the edge region of the wafer by the second brushing bristles may be reduced so that a contact time of the first brushing bristles with the central region of the wafer may also be decreased. As a result, a circuit structure in the central region of the wafer may not be removed by the first brushing bristles.

### BRIEF DESCRIPTION OF THE DRAWINGS

Example embodiments will be more clearly understood from the following detailed description taken in conjunction with the accompanying drawings. FIGS. 1 to 16 represent non-limiting, example embodiments as described herein.

FIG. 1 is a perspective view illustrating a brush for cleaning a wafer in accordance with example embodiments;

FIG. 2 is an enlarged perspective view illustrating the brush in FIG. 1;

FIG. 3 is a cross-sectional view illustrating the brush in FIG. 2;

FIG. 4 is an enlarged perspective view illustrating a first brushing bristle of the brush in FIG. 3;

FIG. 5 is an enlarged perspective view illustrating a second brushing bristle of the brush in FIG. 3;

FIG. 6 is a view illustrating an arrangement of the second brushing bristles in FIG. 3;

FIG. 7 is a graph showing a residence time ration in accordance with positions of the first and second brushing bristles in FIG. 3;

FIG. 8 is a graph showing pressures applied to a wafer from the first and second brushing bristles in FIG. 3;

FIG. 9 is a view illustrating a method of designing a pressure gradient using the second brushing bristles in FIG. 3;

FIG. 10 is a graph showing stiffness changes of the second brushing bristle in FIG. 3;

FIG. 11 is a graph showing a material removal of a wafer by the brush in FIG. 3;

FIG. 12 is a cross-sectional view illustrating a brush in accordance with example embodiments;

FIG. 13 is a graph showing pressures applied to a wafer from the first and second brushing bristles in FIG. 12;

FIG. 14 is an enlarged perspective view illustrating a second brushing bristle of a brush in accordance with example embodiments;

FIG. 15 is a cross-sectional view illustrating the second brushing bristle in FIG. 14; and

FIG. 16 is an enlarged perspective view illustrating a second brushing bristle of a brush in accordance with example embodiments.

### DETAILED DESCRIPTION OF THE EMBODIMENTS

Hereinafter, example embodiments will be explained in detail with reference to the accompanying drawings.

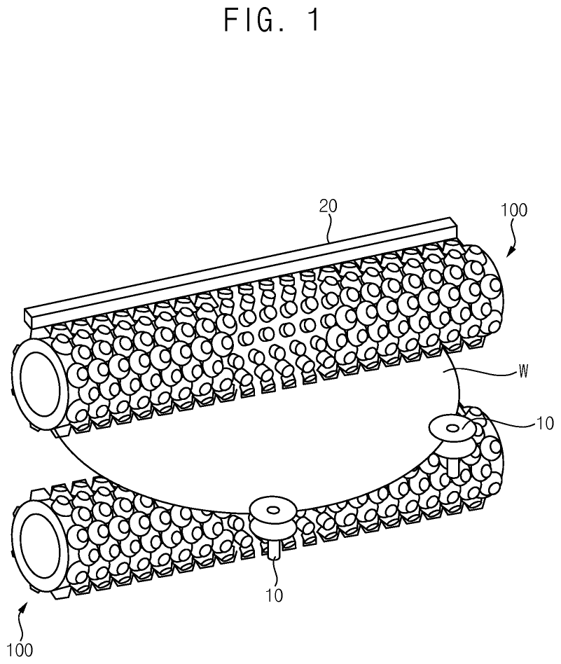

FIG. 1 is a perspective view illustrating a brush for cleaning a wafer in accordance with example embodiments.

A brush 100 of example embodiments may contact a wafer W to remove particles from the wafer W. For example, after a chemical mechanical polishing (CMP) process may be performed on the wafer W, the particles may stain the wafer W (i.e., may remain on the wafer W). The brush 100 may rotatably contact the wafer W to remove the particles from the wafer W. However, the brush 100 of example embodiments may not be restricted for cleaning the wafer W after the CMP process. The brush 100 may be used for cleaning the wafer W after other semiconductor fabrication processes. The term “contact,” as used herein, refers to a direct connection (i.e., physical touching) unless the context indicates otherwise.

Referring to FIG. 1, the brush 100 of example embodiments may be arranged over and under the wafer rotated by rollers 10. The brush 100 may receive a cleaning solution. The cleaning solution may include a chemical solution, a deionized (DI) water, etc. The DI water may be introduced into the brush 100 along an axial direction of the brush 100. The chemical solution may be introduced into the brush 100 through a manifold 20. The brush 100 may be rotated with respect to the axial direction of the brush 100. The rotated brush 100 may contact an upper surface and a lower surface of the wafer W to remove the particles from the upper surface and the lower surface of the wafer W.

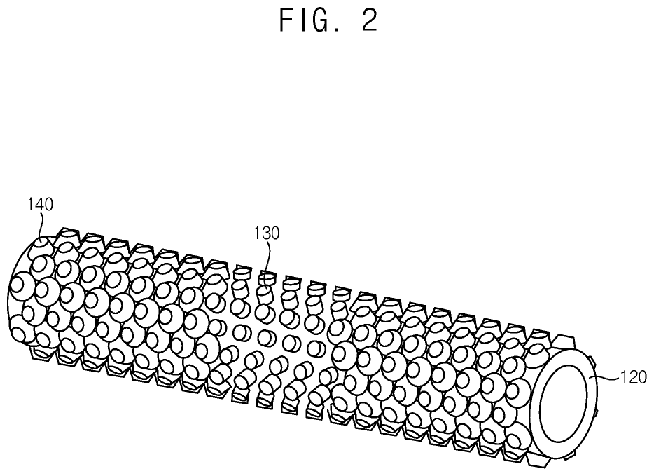

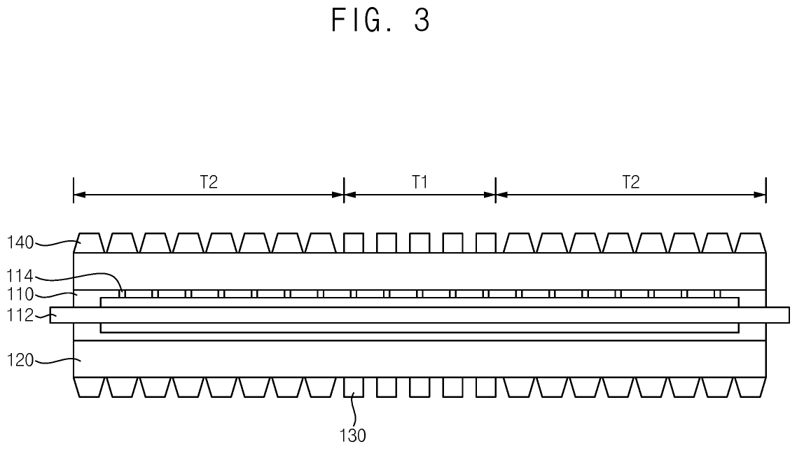

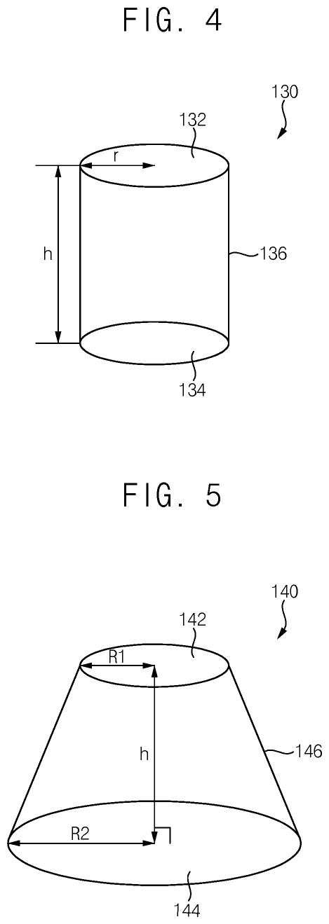

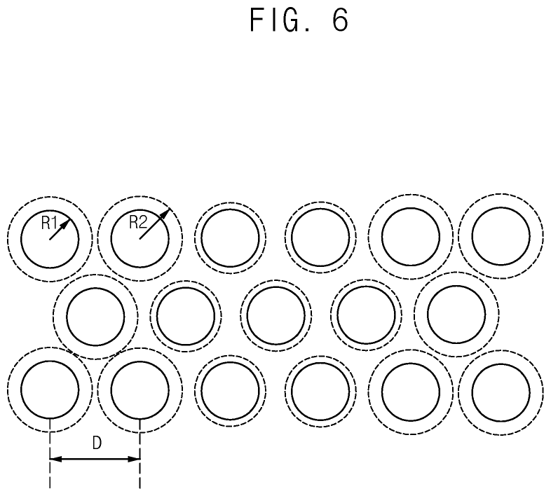

FIG. 2 is an enlarged perspective view illustrating the brush in FIG. 1, FIG. 3 is a cross-sectional view illustrating the brush in FIG. 2, FIG. 4 is an enlarged perspective view illustrating a first brushing bristle of the brush in FIG. 3, FIG. 5 is an enlarged perspective view illustrating a second brushing bristle of the brush in FIG. 3 and FIG. 6 is a view illustrating an arrangement of the second brushing bristles in FIG. 3.

Referring to FIGS. 2 to 6, the brush 100 may include a core 110, a brushing roller 120, a plurality of first brushing bristles 130 and a plurality of second brushing bristles 140.

The core 110 may have a cylindrical shape having a long length. For example, the core 110 may extend lengthwise in a first direction. In drawings, the core 110 may be arranged in a horizontal direction. Thus, the core 110 may have an axial direction corresponding to the horizontal direction. The axial direction may be parallel to the first direction. The core 110 may include a first side surface and a second side surface opposite to the first side surface in the axial direction. The first and second side surfaces may be parallel with each other. The core 110 may further include a side surface extending in the axial direction and connecting the first side surface to the second side surface.

The core 110 may include an inlet passage 112 and a plurality of outlet passages 114. The inlet passage 112 may be formed in the core 110 along the axial direction of the core 110. That is, the inlet passage 112 may be extended from the first side surface to the second side surface in the core 110. Thus, both ends of the inlet passage 112 may be exposed through the first and second side surfaces of the core 110, respectively. The cleaning solution may be introduced into the core 110 through the inlet passage 112.

The outlet passages 114 may be extended from the inlet passage 112. In example embodiments, the outlet passages 114 may be extended in a radial direction of the core 110. The radial direction may be perpendicular to the axial direction of the core 110. That is, the outlet passages 114 may be substantially perpendicular to the inlet passage 112. The present disclosure is not limited thereto. The cleaning solution in the inlet passage 112 may flow the outlet passages 114 along the radial direction of the core 110.

The brushing roller 120 may be arranged on an outer circumferential surface of the core 110. The brushing roller 120 may have a cylindrical shape. Thus, the brushing roller 120 may also have an axial direction corresponding to the axial direction of the core 110. Because the core 110 may be positioned in the brushing roller 120, the brushing roller 120 may have a long hole in which the core 110 is disposed. Thus, the long hole may be extended in the axial direction of the brushing roller 120. The cleaning solution discharged from the outlet passages 114 may be provided to the brushing roller 120 so that the brushing roller 120 may be wetted by the cleaning solution. In example embodiments, the brushing roller 120 may include or may be formed of a soft material such as polyvinyl alcohol (PVA). The present disclosure is not limited thereto. In example embodiments, the brushing roller 120 and the core 110 may be concentric, and the core 110 may be fitted into the long hole of the brushing roller 120.

In example embodiments, at least two regions may be defined on the outer circumferential surface of the brushing roller 120. For example, a first region T1 and a second region T2 may be defined on the outer circumferential surface of the brushing roller 120. The first region T1 and the second region T2 may be defined by a distance from a center of the brushing roller 120 along the axial direction of the brushing roller 120. Particularly, the first region T1 and the second region T2 may be defined by regions of the wafer W contacting the brushing roller 120. The regions of the wafer W may correspond to regions requiring independent controls of pressures applied to the wafer W from the brushing roller 120. For example, the first region T1 may correspond to a region on the outer circumferential surface of the brushing roller 120 contacting a central region of the wafer W. That is, the first region T1 may correspond to a central region of the brushing roller 120. The second region T2 may correspond to a region on the outer circumferential surface of the brushing roller 120 contacting an edge region of the wafer W. That is, the second region T2 may correspond to an edge region of the brushing roller 120.

Because the regions defined on the outer circumferential surface of the brushing roller 120 may correspond to the regions of the wafer W requiring the independent pressure controls, the regions defined on the outer circumferential surface of the brushing roller 120 may be changed in accordance with the regions of the wafer W. Thus, when the wafer W may have at least three regions requiring the independent pressure controls, at least three regions may also be defined on the outer circumferential surface of the brushing roller 120. For example, when the wafer W may have the central region, the edge region and a middle region, the regions defined on the outer circumferential surface of the brushing roller 120 may include the first region T1, the second region T2 and a third region corresponding to the middle region of the wafer W.

In example embodiments, the first region T1 may be positioned within no more than about 50 mm from the center of the brushing roller 120 along the axial direction of the brushing roller 120. The present disclosure is not limited thereto. The second region T2 may be positioned within no less than about 30 mm from the center of the brushing roller 120 along the axial direction of the brushing roller 120, not limited thereto. In this case, the first region T1 and the second region T2 may partially overlap each other. Alternatively, any overlapped region may not exist at a boundary between the first region T1 and the second region T2. For example, the first region T1 may be positioned within no more than about 40 mm from the center of the brushing roller 120 along the axial direction of the brushing roller 120. The second region T2 may be positioned within no less than about 40 mm from the center of the brushing roller 120 along the axial direction of the brushing roller 120. The present disclosure is not limited thereto. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

The first brushing bristles 130 may be arranged on the outer circumferential surface of the brushing roller 120 in the first region T1. The first brushing bristles 130 may be extended in the radial direction of the brushing roller 120. The present disclosure is not limited thereto. Further, the first brushing bristles 130 may be spaced apart from each other by a uniform gap. The present disclosure is not limited thereto. Each of the first brushing bristles 130 may apply a first pressure P1 to the central region of the wafer W. The first brushing bristles 130 may rotatably contact the central region of the wafer W to remove the particles from the central region of the wafer W. In example embodiments, the first brushing bristles 130 may be integrally formed with the brushing roller 120. For example, the first brushing bristles 130 may protrude from the outer circumferential surface of the brushing roller 120 in the radial direction of the brushing roller 120. The first brushing bristles 130 and the brushing roller 120 may include or may be formed of a soft material such as polyvinyl alcohol (PVA). Alternatively, the first brushing bristles 130 may be attached to the outer circumferential surface of the brushing roller 120. For example, the first brushing bristles 130 that are attached to the brushing roller 120 may include or may be formed of a soft material such as polyvinyl alcohol (PVA).

In example embodiments, each of the first brushing bristles 130 may have a cylindrical shape. The present disclosure is not limited thereto. Thus, the first brushing bristle 130 may include a first compression surface 132 having a circular shape, a first connection surface 134 having a circular shape and a first side surface 136. The first compression surface 132 may contact the central region of the wafer W to apply the first pressure P1 to the central region of the wafer W. The first connection surface 134 may be connected to the brushing roller 120. The first compression surface 132 and the first connection surface 134 may have substantially the same radius r. That is, the first compression surface 132 and the first connection surface 134 may have substantially the same area. The first side surface 136 may connect the first compression surface 132 to the first connection surface 134 along a vertical direction that is parallel to the axial direction of the first brushing bristle 130. Thus, the first brushing bristle 130 may have a height h corresponding to a vertical length of the first side surface 136.

The second brushing bristles 140 may be arranged on the outer circumferential surface of the brushing roller 120 in the second region T2. When the first region T1 and the second region T2 of the brushing roller 120 may partially overlap each other, the second brushing bristles 140 may partially overlap the first brushing bristles 130. The second brushing bristles 140 may be extended in the radial direction of the brushing roller 120. The present disclosure is not limited thereto. Further, the second brushing bristles 140 may be spaced apart from each other by a uniform gap D. The present disclosure is not limited thereto. Particularly, the gap D between the second brushing bristles 140 may be substantially the same as the gap between the first brushing bristles 130. The present disclosure is not limited thereto.

Each of the second brushing bristles 140 may apply a second pressure P2 to the edge region of the wafer W. The second pressure P2 may be different from the first pressure P1. The second brushing bristles 140 may rotatably contact the edge region of the wafer W to remove the particles from the edge region of the wafer W. In example embodiments, the second brushing bristles 140 may be integrally formed with the brushing roller 120. For example, the second brushing bristles 140 may protrude from the outer circumferential surface of the brushing roller 120 in the radial direction of the brushing roller 120. The second brushing bristles 140 and the brushing roller 120 may include or may be formed of a soft material such as polyvinyl alcohol (PVA). Alternatively, the second brushing bristles 140 may be attached to the outer circumferential surface of the brushing roller 120. For example, the first brushing bristles 130 that are attached to the brushing roller 120 may include or may be formed of a soft material such as polyvinyl alcohol (PVA).

In example embodiments, each of the second brushing bristles 140 may have a truncated conical shape that is a cone with the top cut off. The present disclosure is not limited thereto. Thus, the second brushing bristle 140 may include a second compression surface 142 having a circular shape, a second connection surface 144 having a circular shape and a second side surface 146. The second brushing bristle 140 may have a height h substantially the same as the height of the first brushing bristle 130. The present disclosure is not limited thereto.

The second compression surface 142 may contact the edge region of the wafer W to apply the second pressure P2 to the edge region of the wafer W. The second pressure P2 may be higher than the first pressure P1. The difference between the first pressure P1 and the second pressure P2 may be illustrated later. The second compression surface 142 may have a first radius R1. The first radius R1 may be substantially the same as the radius r of the first brushing bristle 130. The present disclosure is not limited thereto. When the first radius R1 may be substantially the same as the radius r of the first brushing bristle 130, a contact area between the second compression surface 142 and the wafer W may be substantially the same as a contact area between the first compression surface 132 and the wafer W. The second connection surface 144 may be connected to the brushing roller 120. The second connection surface 144 may have a second radius R2 longer than the first radius R1. That is, the second connection surface 144 may have an area larger than the area of the second compression surface 142. The second side surface 146 may slantly connect the second compression surface 142 to the second connection surface 144. In example embodiments, a ratio of the first radius R1 to the second radius R1 may be about 0.5 to about 1.0. The present disclosure is not limited thereto.

In example embodiments, the first brushing bristle 130 and the second brushing bristle 140 may have the substantially the same height h. Further, the first compression surface 132 of the first brushing bristle 130 and the second compression surface 142 of the second brushing bristle 140 may have substantially the same radius r and R1. The gap D between the first brushing bristles 130 may be substantially the same as the gap D between the second brushing bristles 140. In contrast, the radius of the first connection surface 134 of the first brushing bristle 130 may be different from the radius of the second connection surface 144 of the second brushing bristle 140 to apply the different first and second pressures P1 and P2 to the central region and the edge region of the wafer W.

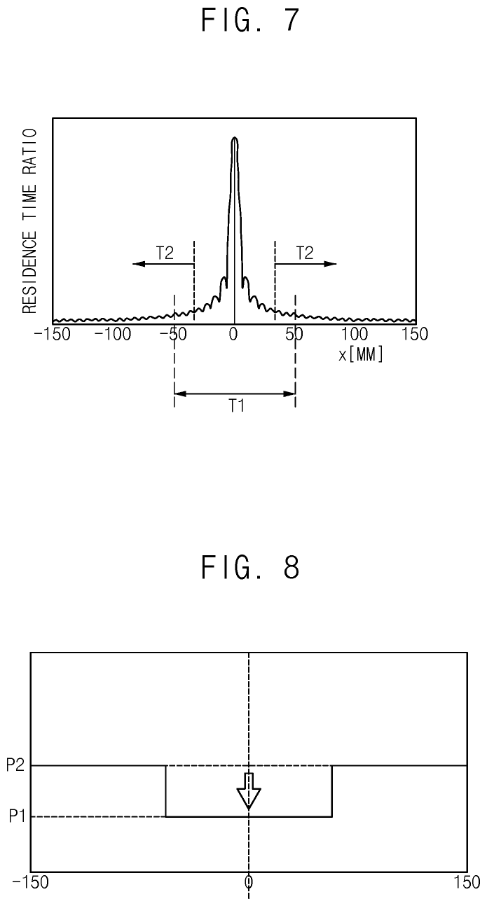

FIG. 7 is a graph showing a residence time ratio in accordance with positions of the first and second brushing bristles in FIG. 3 and FIG. 8 is a graph showing pressures applied to a wafer from the first and second brushing bristles in FIG. 3.

A residence time may mean a contact time between the wafer W and the brushing bristles from a start time to a finish time in a cleaning process. A residence time ratio (RTR) may mean a relative time ratio of the regions of the wafer W contacting the brushing bristles.

When the brushing bristles may apply a same pressure to the wafer W, a time for removing the particles in the edge region of the wafer W may be longer than a time for removing the particles in the central region of the wafer W. Thus, although the particles in the central region of the wafer W may already be removed, the brushing bristles may continuously contact the central region of the wafer W until the particles in the edge region of the wafer W may be completely removed. As a result, a circuit structure in the central region of the wafer W may be damaged by the brushing bristles.

Therefore, as shown in FIG. 7, it can be noted that a high RTR, which may represent a ratio of a contact time between the first brushing bristles 130 and the central region of the wafer W to a contact time between the second brushing bristles 140 and the edge region of the wafer W, may occur at the central region of the wafer W.

However, as shown in FIG. 8, because the second pressure P2, which may be applied to the edge region of the wafer W by the second brushing bristles 140, may be higher than the first pressure P1, which may be applied to the central region of the wafer W by the first brushing bristles 130, a time for removing the particles in the edge region of the wafer W using the second brushing bristles 140 may be reduced. Thus, the removals of the particles in the edge region and the central region of the wafer W may be simultaneously completed. As a result, the RTR between the central region of the wafer W and the first brushing bristles 130 may be decreased to prevent a damage of the circuit structure by the first brushing bristles 130.

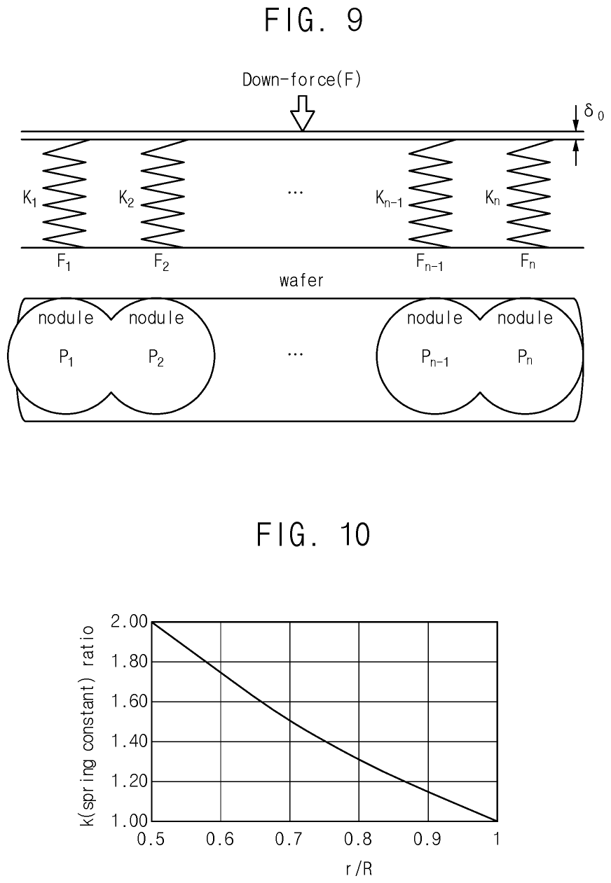

FIG. 9 is a view illustrating a method of designing a pressure gradient using the second brushing bristles in FIG. 3.

Referring to FIG. 9, the second brushing bristle 140 may be modeled as a spring having a spring constant ki. A force F that the second brushing bristle 140 applies to the wafer W may cause a displacement 60 of the second brushing bristle 140. The system displacement & may be multiplied by the spring constant ki to obtain a value of the force F. A contact pressure of the wafer W by the regions may be controlled using a value obtained from the force F divided by a contact area A between the second brushing bristle 140 and the wafer W.

FIG. 10 is a graph showing stiffness changes of the second brushing bristle in FIG. 3.

Referring to FIG. 10, it can be noted that as a ratio of the radius of the first connection surface 134 with respect to the radius of the second connection surface 144 may have been decreased, the spring constant of the second brushing bristle 140, i.e., stiffness of the second brushing bristle 140 may be increased. That is, it can be noted that the stiffness of the second brushing bristle 140 may be increased proportional to increasing the radius of the second connection surface 144.

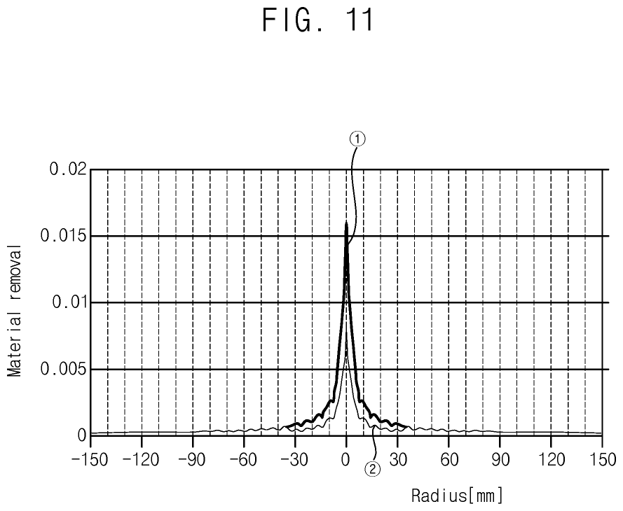

FIG. 11 is a graph showing a material removal of a wafer by the brush in FIG. 3.

In FIG. 11, a line \textcircled{1} may represent a material removal of the wafer W by a conventional brush and a line \textcircled{2} may represent a material removal of the wafer by the brush 100 in FIG. 3.

As shown in FIG. 11, when the brushing bristles may apply a same pressure to the wafer W, it can be noted that a material removal at the central region of the wafer W may be relatively higher than a material removal at the edge region of the wafer W.

In contrast, when the first brushing bristle 130 may apply the first pressure P1 to the central region of the wafer W and the second brushing bristle 140 may apply the second pressure P2 higher than the first pressure P1 to the edge region of the wafer W, it can be noted that a material removal at the central region of the wafer W may be greatly decreased. Thus, the circuit structure in the central region of the wafer W may not be damaged by the first brushing bristle 130.

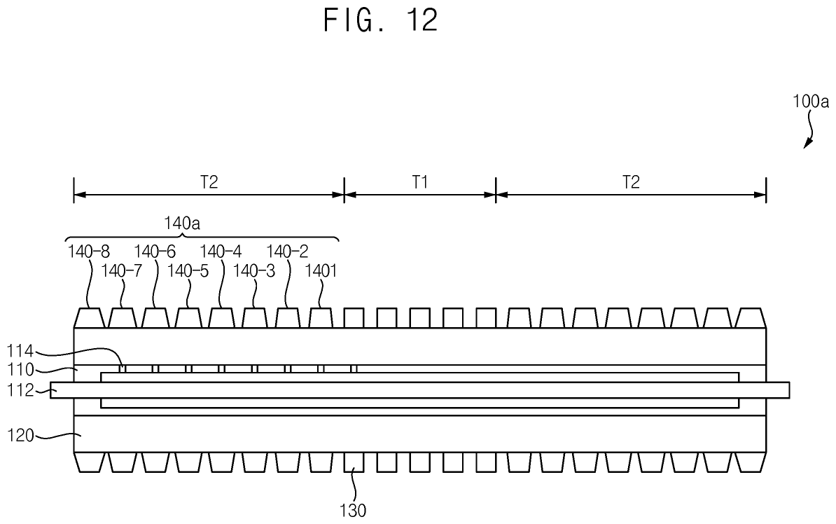

FIG. 12 is a cross-sectional view illustrating a brush in accordance with example embodiments and FIG. 13 is a graph showing pressures applied to a wafer from the first and second brushing bristles in FIG. 12.

Referring to FIG. 12, a brush 100a of example embodiments may include second brushing bristles 140a having a truncated conical shape. For example, the second brushing bristles 140a may include a 2-1 brushing bristle 140-1, a 2-2 brushing bristle 140-2, a 2-3 brushing bristle 140-3, a 2-4 brushing bristle 140-4, a 2-5 brushing bristle 140-5, a 2-6 brushing bristle 140-6, a 2-7 brushing bristle 140-7 and a 2-8 brushing bristle 140-8. The present disclosure is not limited thereto. Particularly, second connection surfaces of the 2-1 brushing bristle 140-1, the 2-2 second brushing bristle 140-2, the 2-3 brushing bristle 140-3, the 2-4 brushing bristle 140-4, the 2-5 brushing bristle 140-5, the 2-6 brushing bristle 140-6, the 2-7 brushing bristle 140-7 and the 2-8 brushing bristle 140-8 may have different second radii. For example, the second radii may be gradually increased from the central region to the edge region of the brushing roller 120. Particularly, the second radius of the second connection surface in the 2-2 brushing bristle 140-2 may be longer than the second radius of the second connection surface in the 2-1 brushing bristle 140-1. The second radius of the second connection surface in the 2-3 brushing bristle 140-3 may be longer than the second radius of the second connection surface in the 2-2 brushing bristle 140-2. The second radius of the second connection surface in the 2-4 brushing bristle 140-4 may be longer than the second radius of the second connection surface in the 2-3 brushing bristle 140-3. The second radius of the second connection surface in the 2-5 brushing bristle 140-5 may be longer than the second radius of the second connection surface in the 2-4 brushing bristle 140-4. The second radius of the second connection surface in the 2-6 brushing bristle 140-6 may be longer than the second radius of the second connection surface in the 2-5 brushing bristle 140-5. The second radius of the second connection surface in the 2-7 brushing bristle 140-7 may be longer than the second radius of the second connection surface in the 2-6 brushing bristle 140-6. The second radius of the second connection surface in the 2-8 brushing bristle 140-8 may be longer than the second radius of the second connection surface in the 2-7 brushing bristle 140-7.

Thus, as shown in FIG. 13, pressures applied to the wafer W from the 2-1 brushing bristle 140-1, the 2-2 brushing bristle 140-2, the 2-3 brushing bristle 140-3, the 2-4 brushing bristle 140-4, the 2-5 brushing bristle 140-5, the 2-6 brushing bristle 140-6, the 2-7 brushing bristle 140-7 and the 2-8 brushing bristle 140-8 may be gradually increased. That is, the 2-8 brushing bristle 140-8 may apply the highest pressure to the wafer W. The 2-1 brushing bristle 140-1 may apply the lowest pressure to the wafer W.

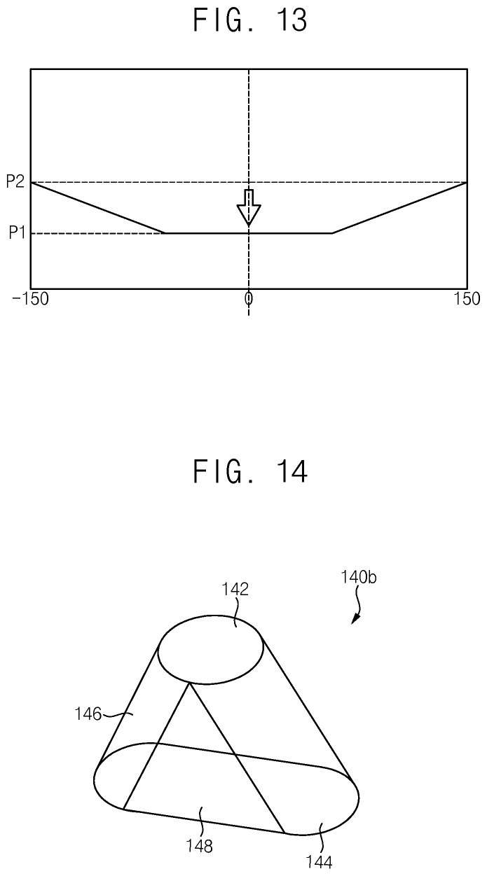

FIG. 14 is an enlarged perspective view illustrating a second brushing bristle of a brush in accordance with example embodiments and FIG. 15 is a cross-sectional view illustrating the second brushing bristle in FIG. 14.

A second brushing bristle 140b of example embodiments may have a structure substantially the same as the structure of the second brushing bristle 140 in FIG. 5 except for further including a control surface. Thus, any further illustrations with respect to the same structure may be omitted herein for brevity.

Referring to FIGS. 14 and 15, the control surface 148 may be formed at the second side surface 146 of the second brushing bristle 140b. The control surface 148 may have a triangular planar shape connecting the second compression surface 142 to the second connection surface 144. The control surface 148 may have a gradually increasing width W from the second compression surface 142 to the second connection surface 144. Particularly, a length L1 between a lower end of the control surface 148 and an outermost lower end of the second side surface 146 may be substantially the same as the first radius R1 of the second compression surface 142. The present disclosure is not limited thereto. Thus, a pressure applied to the edge region of the wafer W from the second brushing bristle 140b may be controlled by changing the lower width W of the control surface 148.

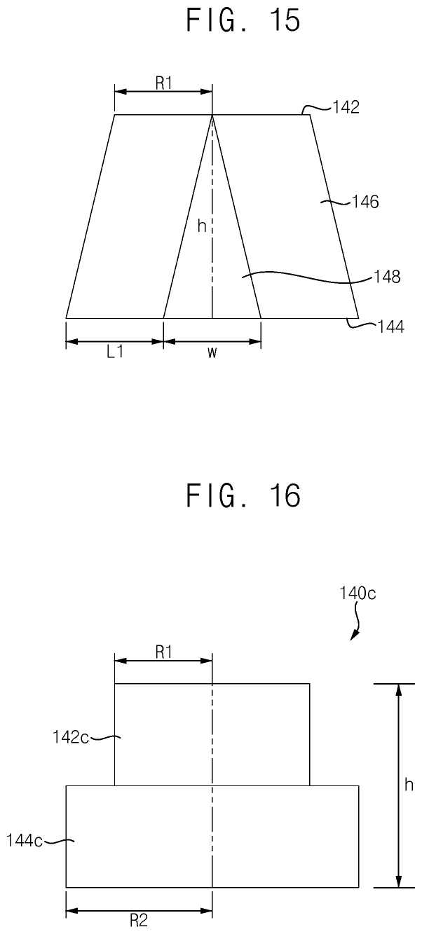

FIG. 16 is an enlarged perspective view illustrating a second brushing bristle of a brush in accordance with example embodiments.

Referring to FIG. 16, a second brushing bristle 140c of example embodiments may include an upper brushing bristle 142c and a lower brushing bristle 144c. The upper brushing bristle 142c may overlap the lower brushing bristle 144c. The upper brushing bristle 142c and the lower brushing bristle 144c may be integrally formed with each other.

The upper brushing bristle 142c may have a cylindrical shape. The upper brushing bristle 142c may have a first radius R1 substantially the same as the first radius R1 of the second brushing bristle 140 in FIG. 5.

The lower brushing bristle 144c may have a cylindrical shape. The lower brushing bristle 144c may have a second radius R2 substantially the same as the second radius R2 of the second brushing bristle 140 in FIG. 5. That is, the lower brushing bristle 144c may have an area larger than an area of the upper brushing bristle 142c.

According to example embodiments, the second pressure, which may be applied to the edge region of the wafer from the second brushing bristles having the truncated conical shape in the edge region of the brushing roller, may be higher than the first pressure, which may be applied to the central region of the wafer from the first brushing bristles having the cylindrical shape in the central region of the brushing roller. Thus, particle removal efficiency by the second brushing bristles may be higher than particle removal efficiency by the first brushing bristles. Therefore, a time for removing particles in the edge region of the wafer by the second brushing bristles may be reduced so that a contact time of the first brushing bristles with the central region of the wafer may also be decreased. As a result, a circuit structure in the central region of the wafer may not be removed by the first brushing bristles.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A brush for cleaning a wafer, the brush comprising:
a core extending lengthwise in a first direction;
a brushing roller arranged on an outer circumferential surface of the core and having a first region and a second region defined at an outer circumferential surface of the brushing roller;
a plurality of first brushing bristles extending from the first region in a radial direction of the brushing roller, wherein the radial direction of the brushing roller is perpendicular to the first direction; and
a plurality of second brushing bristles extending from the second region in the radial direction of the brushing roller,
wherein each of the plurality of first brushing bristles has a first shape, and
wherein each of the plurality of second brushing bristles has a second shape different from the first shape.

2. The brush of claim 1,
wherein the first region corresponds to a central region at the outer circumferential surface of the brushing roller and contacts a central region of the wafer, and
wherein the second region corresponds to an edge region at the outer circumferential surface of the brushing roller and contacts an edge region of the wafer.

3. The brush of claim 2,
wherein the first region is within no more than about 50 mm from a center of the brushing roller in an axial direction of the brushing roller,
wherein the second region is within no less than about 30 mm from the center of the brushing roller in the axial direction of the brushing roller, and
wherein the axial direction of the brushing roller is parallel to the first direction.

4. The brush of claim 2,
wherein each of the plurality of first brushing bristles comprises:
a first compression surface;
a first connection surface; and
a first side surface connecting the first compression surface to the first connection surface,
wherein the first compression surface contacts the central region of the wafer at a first pressure,
wherein the first connection surface is connected to the brushing roller, and
wherein the first compression surface and the first connection surface have substantially the same radius.

5. The brush of claim 4,
wherein each of the plurality of first brushing bristles has a cylindrical shape.

6. The brush of claim 4,
wherein each of the plurality of second brushing bristles comprises:
a second compression surface;
a second connection surface; and
a second side surface connecting the second compression surface to the second connection surface,
wherein the second compression surface contacts the edge region of the wafer at a second pressure,
wherein the second pressure is different from the first pressure,
wherein the second connection surface is connected to the brushing roller, and
wherein the second compression surface has a first radius, and the second connection surface has a second radius longer than the first radius.

7. The brush of claim 6,
wherein each of the plurality of second brushing bristles has a truncated conical shape.

8. The brush of claim 6,
wherein the first radius is substantially the same as the radius of each of the plurality of first brushing bristles.

9. The brush of claim 6,
wherein the plurality of second radii of the plurality of second brushing bristles are the same.

10. The brush of claim 6,
wherein the plurality of second brushing bristles include a plurality of brushing bristles that are arranged along an axial direction of the brushing roller, and
wherein the plurality of second radii of the plurality of brushing bristles are gradually increased in a direction from the central region to the edge region of the brushing roller.

11. The brush of claim 6,
wherein a ratio of the first radius of the second compression surface to the second radius of the second connection surface has a value selected from a range of about 0.5 to about 1.0.

12. The brush of claim 6,
wherein each of the plurality of second brushing bristles further comprises a control surface, and
wherein, in each second brushing bristle, the control surface is formed at the second side surface and connects the second compression surface to the second connection surface.

13. The brush of claim 12,
wherein the control surface has a gradually increasing width in a direction from the second compression surface to the second connection surface.

14. The brush of claim 13,
wherein, in each second brushing bristle, a length between a lower end of the control surface and an outermost lower end of the second side surface is substantially the same as the first radius of the second compression surface.

15. The brush of claim 1,
wherein the plurality of first and second brushing bristles have substantially the same height.

16. A brush for cleaning a wafer, the brush comprising:
a core extending lengthwise in a first direction;
a brushing roller arranged on an outer circumferential surface of the core, the brushing roller having a central region and an edge region defined at an outer circumferential surface of the brushing roller;
a plurality of first brushing bristles, wherein each of the plurality of first brushing bristles has a cylindrical shape that extends from the central region in a radial direction of the brushing roller, and wherein each of the plurality of first brushing bristles contacts a central region of the wafer at a first pressure; and
a plurality of second brushing bristles, wherein each of the plurality of second brushing bristles has a truncated conical shape that extends from the edge region in the radial direction of the brushing roller, and wherein each of the plurality of second brushing bristles contacts an edge region of the wafer at a second pressure higher than the first pressure,
wherein the plurality of first and second brushing bristles have substantially the same height,
wherein each of the plurality of second brushing bristles comprises:
a compression surface;
a connection surface; and
a side surface connecting the compression surface to the connection surface,
wherein the compression surface contacts the edge region of the wafer at the second pressure,
wherein the connection surface is connected to the brushing roller, and
wherein the compression surface has a first radius, and the connection surface has a second radius longer than the first radius.

17. The brush of claim 16,
wherein the first radius is substantially the same as a radius of the cylindrical shape of each of the plurality of first brushing bristles.

18. The brush of claim 16,
wherein the central region of the brushing roller is within no more than about 50 mm from a center of the brushing roller in an axial direction of the brushing roller,
wherein the edge region of the brushing roller is within no less than about 30 mm from the center of the brushing roller in the axial direction of the brushing roller, and
wherein the axial direction of the brushing roller is parallel to the first direction.

19. A brush for cleaning a wafer, the brush comprising:
a core extending lengthwise in a first direction;
a brushing roller arranged on an outer circumferential surface of the core and having a central region and an edge region defined at an outer circumferential surface of the brushing roller;
a plurality of first brushing bristles, wherein each of the plurality of first brushing bristles has a cylindrical shape that extends from the central region in a radial direction of the brushing roller, and wherein each of the plurality of first brushing bristles contacts a central region of the wafer at a first pressure; and
a plurality of second brushing bristles, wherein each of the plurality of second brushing bristles has a truncated conical shape that extends from the edge region in the radial direction of the brushing roller, and wherein each of the plurality of second brushing bristles contacts an edge region of the wafer at a second pressure higher than the first pressure,
wherein the plurality of first and second brushing bristles have substantially the same height,
wherein each of the second brushing bristles comprises:
a compression surface,
a connection surface, and
a side surface connecting the compression surface to the connection surface,
wherein the compression surface contacts the edge region of the wafer at the second pressure,
wherein the connection surface is connected to the brushing roller,
wherein the compression surface has a first radius, and the connection surface has a second radius longer than the first radius,
wherein the plurality of second brushing bristles include a plurality of brushing bristles that are arranged along the first direction, and the plurality of second radii of the plurality of brushing bristles are gradually increased in a second direction from the central region to the edge region of the brushing roller, and
wherein the second direction is parallel to the first direction.

20. The brush of claim 19,
wherein the first radius is substantially the same as a radius of each of the plurality of first brushing bristles.
